(19) United States
(12) Patent Application Publication
(10) Pub. No.: US 2007/0187758 A1
(43) Pub. Date: Aug. 16, 2007

(54) SB-MOSFET (Schottky barrier metal-oxide-semiconductor field effect transistor) with low barrier height and fabricating method thereof

(76) Inventors: Myung Sim Jun, Daejeon (KR); Moon Gyu Jang, Daejeon (KR); Yark Yeon Kim, Daejeon (KR); Chel Jong Choi, Daejeon (KR); Byoung Chul Park, Daejeon (KR); Seong Jae Lee, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/635,179

(22) Filed: Dec. 7, 2006

(30) Foreign Application Priority Data
Dec. 7, 2005 (KR) 10-2005-0119082
Aug. 8, 2006 (KR) 10-2006-0074492

(51) Int. Cl. H01L 27/12

(52) U.S. Cl. 257/347

(57) ABSTRACT

Provided is a high-performance n-type Schottky barrier tunneling transistor with low Schottky barrier for electrons due to a Schottky junction formed on a Si (111) surface created through anisotropic etching. The Schottky barrier tunneling transistor includes: a silicon on insulator (SOI) substrate; a source and a drain formed on the SOI substrate; a channel formed between the source and the drain; a gate insulating layer and a gate electrode sequentially formed on the channel; and a sidewall insulating layer formed on both sidewalls of the gate insulating layer and the gate electrode, wherein an interface between the source/drain and the channel is on a Si (111) in the channel, and the source and drain consists of metal silicide through silicidation with a predetermined metal and forms a Schottky junction with the silicon channel.

### CROSS-REFERENCE TO RELATED APPLICATION

This application claims priority to and the benefit of Korean Patent Application Nos. 2005-119082, filed Dec. 7, 2005, and 2006-74492, filed Aug. 8, 2006, the disclosures of which are incorporated herein by reference in their entirety.

### BACKGROUND

1. Field of the Invention

The present invention relates to fabrication of semiconductor devices, and more particularly, to a Schottky barrier tunneling transistor and a method of fabricating the same.

2. Discussion of Related Art

Modern semiconductor technology has been developed for devices with smaller size, faster switching speed and lower power consumption. For more than 30 years, integration has followed Gordon Moore's law that the number of transistors per integrated circuit would double every 18 months. Currently, the gate length of metal-oxide-semiconductor field effect transistors (MOSFETs) has become smaller than 100 nm.

Meanwhile, International Technology Roadmap for Semiconductors (ITRS) literature issued in 2003 predicted that the gate length of transistors would be 30 nm in 2005 and 10 nm in 2015.

As the gate length of MOSFET is reduced to less than 100 nm, the various problems such as short channel effects are encountered. Also, tunneling current through the thin gate oxide is generated, a threshold voltage varies due to non-uniform impurity distribution in a channel, and an insulating layer is deteriorated due to charges trapped therein by a hot-carrier effect. These factors degrade the performance and reliability of MOSFETs.

Shallow junctions are required to reduce short channel effects. However, it is difficult to make shallow and uniform junctions by ion implantation commonly used to form a source and a drain. Moreover, the resulting source and drain has a high sheet resistance comparable to channel resistance. The highly resistive source/drain influences DC characteristics as well as the operation speed of the transistor.

Researchers are attempting to overcome these obstacles by using new materials, and structures.

One example is a Schottky barrier tunneling transistor in which a source and a drain are formed of metal silicide, a metal compound of silicon, not by doping, such that Schottky contact is formed between the source/drain and the channel.

FIG. 1 illustrates the structure of an ordinary Schottky barrier tunneling transistor.

Referring to FIG. 1, a Schottky barrier tunneling transistor consists of a channel region 8 with low impurity concentration on a buried oxide layer 2, source and drain regions 3a and 3b subjected to silicidation with a predetermined metal, a gate insulating layer 4 and a gate electrode 6 sequentially formed on the channel region 8, and a sidewall insulating layer 5 formed on both sidewalls of the gate insulating layer 4 and the gate electrode 6.

In this case, when a silicon on insulator (SOI) layer has (100) orientation that is the most widely used, and an erbium silicide/silicon Schottky junction is formed to implement a low barrier height, the Schottky barrier height is about 0.4 V for electrons.

The channel leakage current in Schottky barrier tunneling transistor can be well controlled even when the gate length is around 50 nm or less. Also, the Schottky barrier tunneling transistor can be fabricated with a shallow junction and low sheet resistance since the source and the drain are formed of metal. Accordingly, the Schottky barrier tunneling transistor has the advantage of a small size, high-integration and high-speed device.

In addition, as the transistor gets smaller, the gate insulating layer 4 needs to be thinner to effectively control the electrical potential of the channel. However, since leakage current from the gate electrode 6 increases as the gate insulating layer 4 gets thinner, materials with high dielectric constant (high-k) as a gate dielectric are replacing silicon dioxide in current research.

Furthermore, although a polycrystalline silicon gate has advantages that its work function can be adjusted by doping and its process is comparatively easy, it forms depletion layer and has large resistance. Accordingly, metal nitride gate or metal silicide gate is considered as a substitution of a poly-silicon gate.

Unlike a conventional process of a MOSFET, the Schottky barrier tunneling transistor configured as shown in FIG. 1 does not require an annealing process for activation of implanted impurities in source and drain regions 3a and 3b because the regions are formed of metal silicide. Thus, the temperature in a fabrication process is as low as 600° C. or lower, which makes it possible to use a silicide metal gate and a high-k material as a gate insulating layer.

Schottky barrier height at the junction of metal silicide and silicon is a critical factor determining performance of the Schottky barrier tunneling transistor. That is, a Schottky barrier transistor with low barrier height has an excellent turn-on/off current characteristic while a Schottky transistor with high barrier height has high resistance, low on-current and high off-current due to inflow of counter charges.

Thus, in an n-type Schottky barrier tunneling transistor, the source/drain silicide is made of a metal with a low work function, such as erbium, ytterbium, yttrium, or samarium, in order to form such low Schottky barrier height. However, the Schottky barrier height depends on interface states between metal and silicon, a fine structure of the interface, and the like, as well as a work function of metal and electron affinity of silicon.

These factors make it difficult to control Schottky barrier height because Schottky barrier height becomes independent of the work function of metal in contact with a semiconductor.

### SUMMARY OF THE INVENTION

The present invention is directed to implementation of a high-performance n-type Schottky barrier tunneling transistor that has low Schottky barrier height for electrons by forming a rare earth silicide on Si (111) created by anisotropic etching.

One aspect of the present invention provides a Schottky barrier tunneling transistor comprising: a silicon substrate; a buried oxide layer; a SOI channel; a gate insulating layer and a gate electrode sequentially formed on the channel; and a sidewall insulating layer formed on both sidewalls of the gate insulating layer and the gate electrode, and the source/drain metal silicide contacted with a Si (111) on the channel.

Another aspect of the present invention provides a method of fabricating a Schottky barrier tunneling transistor comprising the steps of: defining a active region including the source/drain and channel by patterning an SOI layer; forming a gate insulating layer, a poly-silicon layer, and a silicon nitride layer on the channel region; etching the gate insulating layer, the poly silicon layer, and the silicon nitride layer except the gate electrode region; forming a sidewall insulating layer on both sidewalls of the gate insulating layer, the poly-silicon layer, and the silicon nitride layer; anisotropically etching the SOI layer to create a Si (111) surface; removing the silicon nitride layer; depositing a metal of a predetermined thickness on the entire surface of resultant substrate and forming Schottky contact on the Si (111) of the channel through silicidation.

The SOI layer may be formed to a thickness of 100 nm or less.

The SOI layer may be a lightly doped substrate having an impurity concentration of 10¹⁷ cm⁻³ or less.

The gate insulating layer may be formed of one of a silicon oxide layer (SiO2), an aluminum oxide layer (Al₂O₃), and a hafnium oxide layer (HfO₂).

The gate electrode may be formed of one of polysilicon, aluminum, and titanium (Ti).

The sidewall insulating layer may be formed of a silicon oxide layer (SiO₂).

The gate length may be 50 nm or less.

The anisotropic etching may comprise anisotropic wet-etching using potassium hydroxide (KOH) or THAM (tetramethyl-ammonium-hydroxide).

The step of forming the Schottky junction may comprise the step of removing a metal that does not react to silicide.

The metal may be one of Erbium (Er), ytterbium (Yb), Samarium (Sm), Yttrium (Y), Gadolinium (Gd), Terbium (Tb), and Cerium (Ce).

The silicidation may comprise annealing at a temperature of 400° C. to 600° C.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1 illustrates the structure of a ordinary Schottky barrier tunneling transistor;

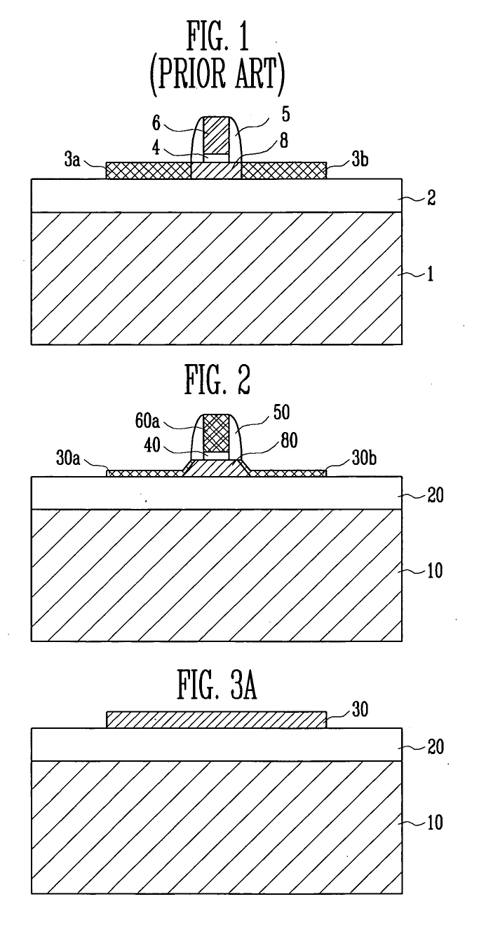

FIG. 2 illustrates the structure of a Schottky barrier tunneling transistor according to an exemplary embodiment of the present invention;

FIGS. 3A to 3F are cross-sectional views illustrating a method of fabricating a Schottky barrier tunneling transistor according to an exemplary embodiment of the present invention; and

FIG. 4 illustrates results of measuring electrical characteristics of erbium-silicided Schottky diodes fabricated on a Si (100) and a Si (111), respectively.

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various modified forms. The exemplary embodiments are described to make this disclosure complete and enable practice of the present invention by those of ordinary skill in the art.

A Schottky barrier tunneling transistor and a method of fabricating the same according to exemplary embodiments of the present invention will be described with reference to the accompanying drawings.

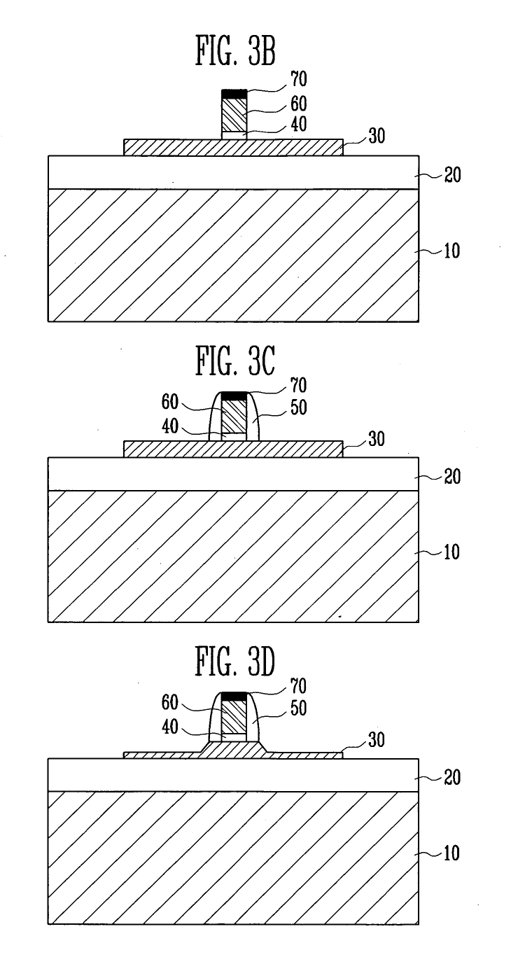

FIG. 2 illustrates the structure of a Schottky barrier tunneling transistor according to an exemplary embodiment of the present invention.

Referring to FIG. 2, the Schottky barrier tunneling transistor includes a metal silicide source and drain 30a and 30b, a channel 80, a gate insulating layer 40 and a gate electrode 60a sequentially formed on the channel 80, and a sidewall insulating layer 50 formed on both sidewalls of the gate insulating layer 40 and the gate electrode 60a. In this case, the inclined plane of the channel 80 contacted with the source and drain 30a and 30b is a Si (111). the source and drain 30a and 30b is a silicide of a predetermined metal.

The source and drain 30a and 30b coupled to Si (111) plane forms a Schottky junction.

The wafer may be a silicon-on-insulator (SOI) wafer but is not limited thereto. The substrate may be a bulk silicon substrate.

A method of fabricating a Schottky barrier tunneling transistor according to an exemplary embodiment of the present invention will now be described in detail with reference to the accompanying drawings.

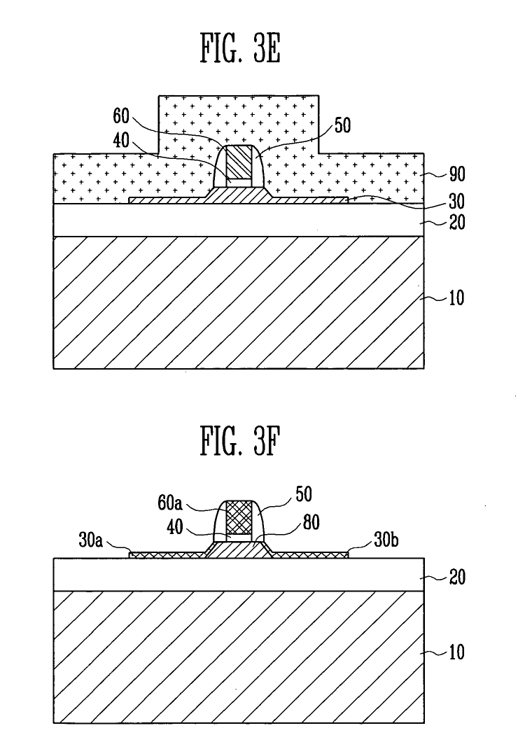

FIGS. 3A to 3F are cross-sectional views illustrating a method of fabricating a Schottky barrier tunneling transistor according to an exemplary embodiment of the present invention

Referring to FIG. 3A, SOI wafer consists of a silicon substrate 10, an insulating layer 20, and a SOI layer 30. The active region is defined in the top silicon using conventional lithography and etching technique.

Preferably, the SOI layer 30 may have a thickness of about 100 nm or less, allowing the gate electrode 60a to efficiently adjust the electric field of the channel region 80 and suppress leakage current.

The SOI layer 30 is a lightly doped substrate having an impurity concentration of 10¹⁷ cm⁻³ or less.

As shown in FIG. 3B, a gate insulating layer 40 and a poly-silicon layer 60 or a metal are sequentially deposited in a predetermined active region on the SOI layer 30, and a silicon nitride layer 70 is then formed thereon to protect the gate electrode layer 60. Then, the gate insulating layer 40, the poly-silicon layer 60, and the silicon nitride layer 70 are patterned and dry-etched using an etch mask, such as photoresist.

The gate insulating layer 40 may be a silicon oxide layer (SiO₂) formed by thermally oxidizing silicon. Alternatively, the gate insulating layer 40 may be a thin film having a high dielectric constant, such as an aluminum oxide layer (Al₂O₃) or a hafnium oxide layer (HfO₂), which makes it possible to effectively apply electric field effect to the channel. Also, a metal such as aluminum or titanium (Ti) instead of poly-silicon 60 may be used to further improve the performance of the Schottky barrier tunneling transistor.

As shown in FIG. 3C, a sidewall spacer is formed by using oxidation and dry etching processes on sidewalls of the gate insulating layer 40, the poly-silicon layer 60, and the silicon nitride layer 70 for preventing electrical connection upon forming silicide in the source, drain and gate electrode.

Here, the sidewall insulating layer 50 may be formed of a material having a possibly low dielectric constant and particularly a silicon oxide layer (SiO₂).

As shown in FIG. 3D, Si(111) on channel region 80 is formed by an anisotropic etching process using potassium hydroxide (KOH) or tetramethyl-ammonium-hydroxide (THAM). Alternatively, the interface may be made by dry etching under appropriate conditions.

As shown in FIG. 3E, the silicon nitride layer 70 left to protect the poly-silicon layer 60 is removed by wet etching or dry etching and a metal 90 is deposited to a predetermined thickness on the substrate.

Here, the wet etching solution having a higher selectivity with respect to silicon nitride than the sidewall insulating layer 50 is used to minimize damage of the sidewall insulating layer 50. The metal 90 may be erbium, ytterbium (Yb), samarium (Sm), yttrium (Y), gadolinium (Gd), terbium (Tb), or cerium (Ce).

Finally, as shown in FIG. 3F, after deposition of metal, the metal silicide is formed on Si (111) by using rapid thermal annealing (RTA) technique. As a result, the metal silicide source and drain 30a and 30b get to form a Schottky junction with the channel region 80 at Si (111).

Here, the silicide is formed only in the source and drain regions 30a and 30b and the gate electrode layer 60a. The non-reactive metal 90 deposited on the insulating layer 20 and the sidewall insulating layer 50 having no silicon is removed by wet etching. The wet etching solution used for removing the non-reactive metal 90 may contain sulphuric acid and peroxide mixed 1:1.

For the silicidation, the annealing temperature ranges from 400° C. to 600° C.

When a metal is used to the gate electrode layer 60a, the silicon nitride layer 70 is formed, a r metal 90 is deposited on the silicon nitride layer, and silicidation process is carried out. Thereafter, the non-reactive metal 90 is removed and then the silicon nitride layer 70 is removed.

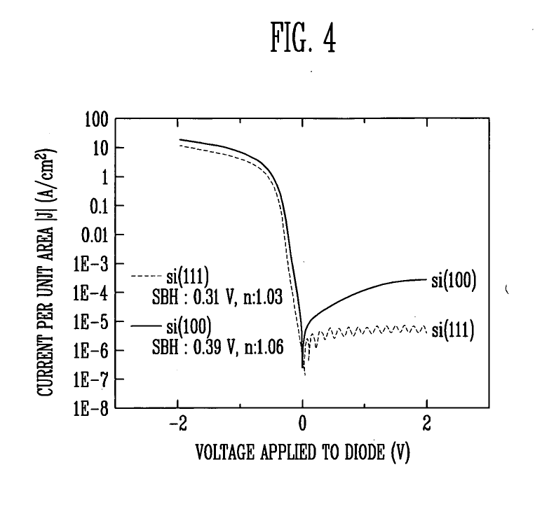

FIG. 4 illustrates results of measuring electrical characteristics of erbium-silicided Schottky diodes fabricated on Si (100) and Si (111), respectively.

Referring to FIG. 4, an erbium silicide/silicon Schottky barrier height (SBH) is 0.39 V for the Si (100) and 0.31 V for the Si (111). That is, the SBH for the Si (111) is 0.08 V lower. Application of it to a Schottky barrier transistor increases a ratio of turn-on current to turn-off current of the transistor, thereby improving characteristics of the transistor.

Furthermore, the extracted ideality factor n of the diode is 1.06 for the Si (100) and 1.03 for the Si (111). It can be seen that the erbium-silicided Schottky contact on Si (111) is superior to that on Si (100).

It can be seen from these experimental results that reliable and high-performance Schottky barrier tunneling transistors can be fabricated according to the present invention.

According to the present invention as described above, it is possible to fabricate a reliable and high-performance Schottky barrier tunneling transistor by solving problems associated with an n-type Schottky barrier tunneling transistor having low saturation current. It is also possible to apply the present invention to realization of future nano-scale devices.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A Schottky barrier tunneling transistor comprising:
a silicon on insulator (SOI) substrate;
a source and a drain formed on the SOI substrate;
a channel formed between the source and the drain;
a gate insulating layer and a gate electrode sequentially formed on the channel; and
a sidewall insulating layer formed on both sidewalls of the gate insulating layer and the gate electrode,
wherein an interface between the source/drain and the channel is formed on a Si (111) of the channel, and the source and drain is subjected to silicidation with a predetermined metal and forms a Schottky junction with the silicon channel.

2. The Schottky barrier tunneling transistor of claim 1, wherein the channel has the inclined plane of Si (111) by an anisotropic etching process.

3. The Schottky barrier tunneling transistor of claim 1, wherein the gate length is formed to 50 nm or less.

4. The Schottky barrier tunneling transistor of claim 1, wherein the substrate comprises any one of a silicon-on-insulator (SOI) substrate and a bulk silicon substrate.

5. A method of fabricating a Schottky barrier tunneling transistor, comprising the steps of:
defining a channel region and source and drain regions by patterning an SOI layer on an SOI substrate;
forming a gate insulating layer, a poly-silicon layer, and a silicon nitride layer on the channel region;
etching the gate insulating layer, the poly-silicon layer, and the silicon nitride layer except the gate electrode region;
forming a sidewall insulating layer on both sidewalls of the gate insulating layer, the poly-silicon layer, and the silicon nitride layer;
anisotropically etching the SOI layer to create a Si (111) surface on the silicon channel;
removing the silicon nitride layer; and
depositing a metal of a predetermined thickness on the entire surface of the resultant substrate and forming Schottky contact on Si (111) of the channel through silicidation.

6. The method of claim 5, wherein the SOI layer is a lightly doped substrate having an impurity concentration of 10¹⁷ cm⁻³ or less.

7. The method of claim 5, wherein the gate insulating layer is formed of one of a silicon oxide layer (SiO₂), an aluminum oxide layer (Al₂O₃), and a hafnium oxide layer (HfO₂).

8. The method of claim 5, wherein the material to be gate electrode is formed of one of poly-silicon, aluminum, and titanium (Ti).

9. The method of claim 5, wherein the sidewall insulating layer is formed of a silicon oxide layer (SiO₂).

10. The method of claim 5, wherein the anisotropic etching includes anisotropic wet-etching using potassium hydroxide (KOH) or THAM (tetramethyl-ammonium-hydroxide).

11. The method of claim 5, wherein the step of forming the Schottky junction interface further includes the step of removing a metal that does not react to silicide.

12. The method of claim 5, wherein the metal is one of Erbium (Eb), ytterbium (Yb), Samarium (Sm), Yttrium (Y), Gadolinium (Gd), Terbium (Tb), and Cerium (Ce).

13. The method of claim 5, wherein the silicidation includes annealing at a temperature of 400° C. to 600° C.
